(19) United States
(12) Patent Application Publication
(10) Pub. No.: US 2013/0145988 A1
(43) Pub. Date: Jun. 13, 2013

(54) Substrate Processing Bubbler Assembly

(71) Applicant: Jay DeDontney, Prunedale, CA (US)

(72) Inventor: Jay DeDontney, Prunedale, CA (US)

(73) Assignee: Intermolecular, Inc., San Jose, CA (US)

(21) Appl. No.: 13/316,766

(22) Filed: Dec. 12, 2011

(51) Int. Cl. C23C 16/44; F25B 21/02

(52) U.S. Cl. 118/724; 62/3.2

(57) ABSTRACT

Embodiments provided herein describe bubbler assemblies for substrate processing systems. The substrate processing bubbler assemblies include an inner shell, an outer shell, and a thermoelectric device. The inner shell is configured to hold a liquid. The outer shell at least partially surrounds the inner shell. The inner shell and the outer shell are sized and shaped such that a gap is formed between the inner shell and the outer shell. The thermoelectric device interconnects the inner shell and the outer shell. The thermoelectric device has a first side adjacent to the inner shell and a second side adjacent to the outer shell and is configured to transfer heat between the first side and the second side thereof.

The present invention relates to bubbler assemblies. More particularly, this invention relates to bubbler assemblies for substrate processing systems.

### BACKGROUND OF THE INVENTION

Chemical Vapor Deposition (CVD) is a vapor based deposition process commonly used in semiconductor manufacturing including but not limited to the formation of dielectric layers, conductive layers, semiconducting layers, liners, barriers, adhesion layers, seed layers, stress layers, and fill layers.

Derivatives of CVD based processes include but are not limited to plasma enhanced chemical vapor deposition (PECVD), high-density plasma chemical vapor deposition (HDP-CVD), sub-atmospheric chemical vapor deposition (SACVD), laser assisted/induced CVD, and ion assisted/induced CVD, metal organic chemical vapor deposition (MOCVD), and atomic layer deposition (ALD).

In CVD processes, the chemicals which are used are often in the liquid state (i.e., liquid sources). In order to be used in CVD processes, liquid sources have to be evaporated or brought into the vapor phase. If the vapor pressure of a particular liquid source is sufficiently high, evaporation may be achieved by heating the liquid source in an evaporator and controlling the vapor flow to the processing chamber of the CVD tool using, for example, a mass flow controller (MFC).

However, if the vapor pressure is too low to create a sufficient pressure drop across the MFC for reliable regulation of the vapor flow, an alternate method is commonly used. In this method, a second high pressure “carrier” gas is supplied to the MFC, which has sufficient pressure for proper operation of the MFC. This carrier gas is “bubbled” through the closed container containing a liquid source to enhance evaporation. As the carrier gas transits through the container, it picks an additional amount of vapor from the liquid precursor within the container. The devices used for such a process are referred to as bubblers or bubbler assemblies (or systems). To further control evaporation in bubblers, the temperature of the liquid source may also be regulated (i.e., by cooling or heating).

One issue with existing cooling bubblers is that the systems often have cold surfaces that are exposed to the ambient air, which may lead to condensation of moisture on the outer surfaces. This moisture may accumulate and trip spill sensors, or create other undesirable hazards such as having water in proximity to electrical equipment, or prompting corrosion of components. Additionally, some existing bubblers are relatively large, complex, and expensive, as a coolant (e.g., water) is often required to serve as a heat transfer medium.

### BRIEF DESCRIPTION OF THE DRAWINGS

Various embodiments of the invention are disclosed in the following detailed description and the accompanying drawings:

FIG. 1 is an isometric view of a bubbler assembly for a substrate processing system, according to one embodiment of the present invention;

FIG. 2 is a front view of the bubbler assembly of FIG. 1;

FIG. 3 is a top view of the bubbler assembly taken along line 3-3 in FIG. 2;

FIG. 4 is a cross-sectional view of the bubbler assembly taken along line 4-4 in FIG. 3;

FIG. 5 is a cross-sectional view of the bubbler assembly taken along line 5-5 in FIG. 2; and

FIG. 6 is a schematic block diagram of a substrate processing system according to one embodiment of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Generally, the invention provides a bubbler assembly for substrate processing, which provides improved cooling and minimizes exterior condensation. This is accomplished by using a double-walled body with a gap between the inner and outer shells of the body. Heat transfer is performed by one or more thermoelectric devices (or modules) that are positioned within the gap. In one embodiment, the cold sides of the thermoelectric modules contact the inner shell and the hot sides contact the outer shell. The gap may be evacuated to improve insulation and prevent any liquid from condensing on the outer surfaces of the assembly.

In one embodiment, a substrate processing bubbler assembly is provided. The substrate processing bubbler assembly includes an inner shell, an outer shell, and a thermoelectric device. The inner shell is configured to hold a liquid. The outer shell at least partially surrounds the inner shell. The inner shell and the outer shell are sized and shaped such that a gap is formed between the inner shell and the outer shell. The thermoelectric device interconnects the inner shell and the outer shell. The thermoelectric device has a first side adjacent to the inner shell and a second side adjacent to the outer shell and is configured to transfer heat between the first side and the second side thereof.

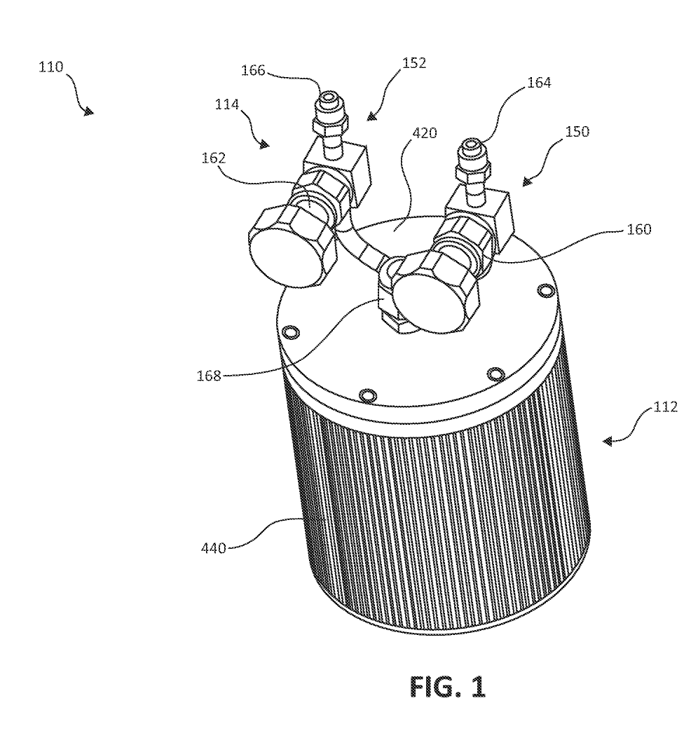

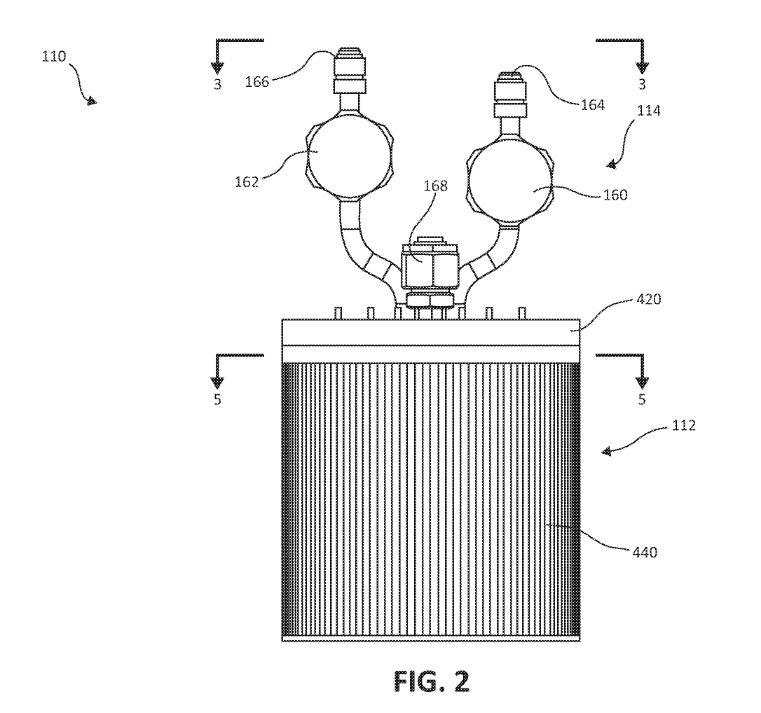

FIGS. 1-5 illustrate a bubbler assembly (or system) 110 for a substrate processing tool (or system), according to one embodiment of the present invention. The bubbler assembly 110 includes a main body 112 and a fluid conduit assembly 114. The main body 112 is substantially cylindrical in shape. The fluid conduit assembly 114 is coupled to and extends from an upper end of the main body 112.

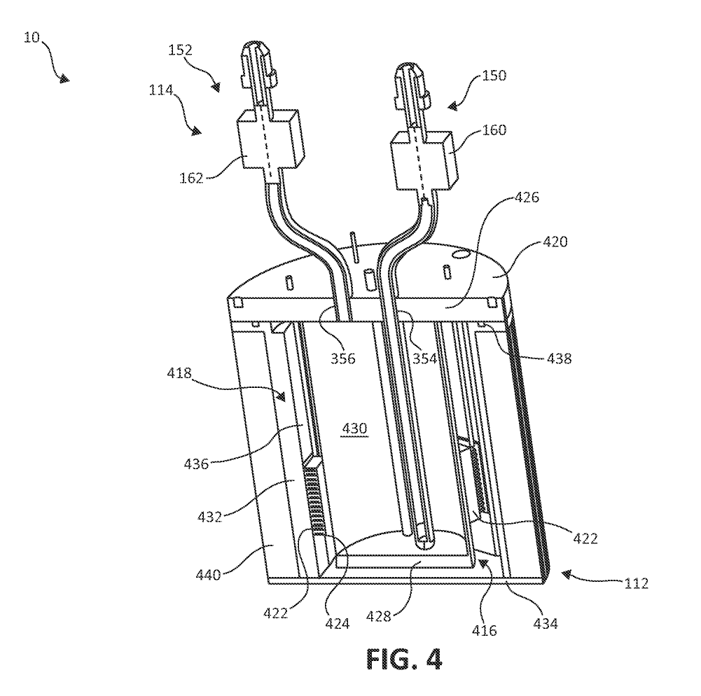

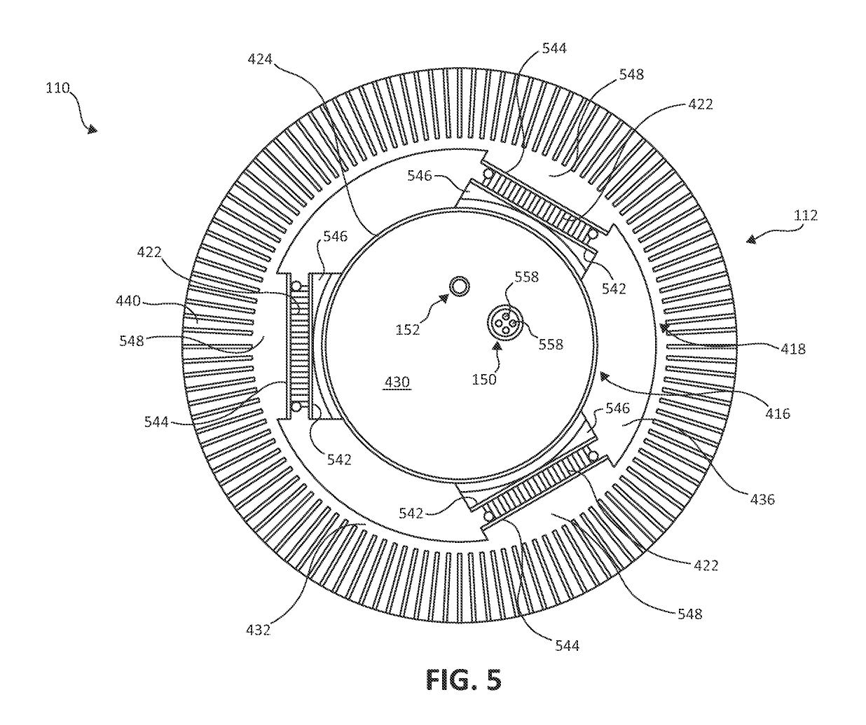

Referring specifically to FIGS. 4 and 5, the main body 112 includes an inner shell 416, an outer shell 418, a top piece 420, and an array of thermoelectric modules 422. The inner shell 416 is substantially cylindrical in shape and includes a sidewall 424, an upper end piece 426 (which is integral with the top piece 420), and a lower end piece 428. As shown, the upper end piece 426 and the lower end piece 428 are connected at opposing ends of the sidewall 424 such that the inner shell 416 encloses a reservoir 430.

The outer shell 418 has a similar shape to the inner shell 416 and also includes a sidewall 432 and a lower end piece 434. The top piece 420 of the main body 112 (including the upper end piece 426 of the inner shell) forms an upper end piece of the outer shell 418. The outer shell 418 is sized and shaped such that a gap (or space) 436 is formed which extends around (or circumscribes) a periphery of the sidewall 424 of the inner shell 416 (i.e., between the sidewall 424 of the inner shell 416 and the sidewall 432 of the outer shell 418), as well as between the lower end piece 428 of the inner shell 416 and the lower end piece 434 of the outer shell 418.

Referring specifically to FIG. 4, the top piece 420 of the main body 112 is sized to extend beyond the sidewall 424 of the inner shell 416 and is connected to an upper end of the sidewall 432 of the outer shell 418. In the depicted embodiment, an o-ring 438 (or annular sealing member) is positioned within an annular groove in the upper end of the sidewall 432 of the outer shell 418 that extends beyond a periphery of the sidewall 424 of the inner shell 416. The o-ring 438 may be sized such that when the top piece 420 is connected to the sidewall 432 of the outer shell 418, the o-ring is compressed such that the gap 436 is hermetically sealed. During manufacturing, the gap 436 may be evacuated using known methods. As such, little or no air may be in contact with the sidewall 424 of the inner shell 416.

The main body 112 also includes a series of cooling fins 440 arranged around a periphery of the sidewall 432 of the outer shell 418. In one embodiment, the cooling fins 440 are integral with the sidewall 432, as shown in FIG. 5. The components of the main body 112 may be made of, for example, stainless steel or aluminum.

Referring again to FIGS. 4 and 5, the thermoelectric modules 422 are positioned within the gap 436. In the depicted embodiment, three thermoelectric modules 422 are included that are equally spaced around the sidewall 424 of the inner shell 416.

In one embodiment, each of the thermoelectric modules 422 is configured to use the Peltier effect, as is commonly understood, to create a heat flux (or transfer heat) between a first side 542 and a second side 544 thereof, which are indicated in FIG. 5. As such, when power is provided, heat is transferred from the first side (or cold side) 542 to the second side (or hot side) 544. As shown, each of the thermoelectric modules 422 is arranged such that the first side 542 thereof is adjacent to the sidewall 424 of the inner shell 416 and the second side 544 is adjacent to the sidewall 432 of the outer shell 418. In such an arrangement, the thermoelectric modules 422 are used to remove heat from (i.e., to cool) the inner shell 416, and thus any fluid in the reservoir 430. However, in other embodiments, the thermoelectric modules 422 may be arranged in the opposite configuration, with the first side 542 adjacent to the sidewall 432 of the outer shell 418 and the second side 544 is adjacent to the sidewall 424 of the inner shell 416, so as to add heat to (i.e., to heat) the inner shell 416.

In the embodiment shown in FIG. 5, the sidewall 424 of the inner shell 416 further includes a series of inner mounting bosses 546, while the sidewall 432 of the outer shell 418 includes a series of outer mounting bosses 548. As shown, the inner mounting bosses 546 and the outer mounting bosses 548 provide substantially flat surfaces for the interfaces of the first and second sides 542 and 544 with the respective sidewalls 424 and 432. It should also be noted that in at least one embodiment, the thermoelectric modules 422 provide the only direct, physical connections (or contact points), and thus only thermal interfaces, between the sidewall 424 of the inner shell 416 and the sidewall 432 of the outer shell 418.

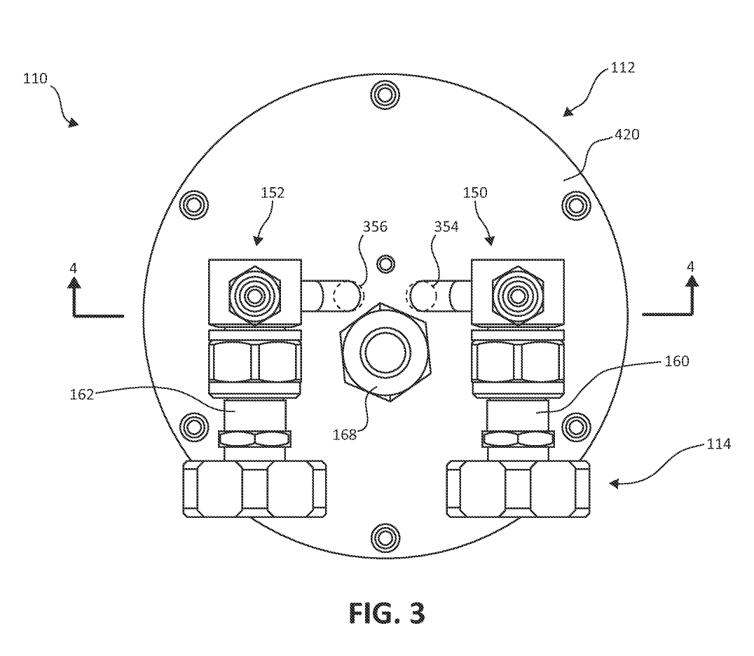

Referring now to FIGS. 1-4, the fluid conduit assembly 114 includes a first fluid conduit 150 and a second fluid conduit 152, which include sections of tubing that are connected to respective openings 354 and 356 (FIGS. 3 and 4) through the top piece 420 of the main body 112. Referring specifically to FIG. 4, the first fluid conduit (or carrier or inlet tube) 150 extends through opening 354 in the top piece 420 and into the reservoir 430 formed by the inner shell 416 of the main body 112 (i.e., towards the lower end piece 428 of the inner shell 416). As such, in embodiment shown in FIG. 4, the first fluid conduit 150 may form a “diptube,” which extends into a processing liquid that is held within the reservoir 430. However, it should be understood that in other embodiments, the first fluid conduit 150 may not extend as far into the reservoir 430 such that the first fluid conduit 150 does not extending into the processing liquid (i.e., a “diptubeless” bubbler).

As shown specifically in FIG. 5, the first fluid conduit 150 includes a series of fluid openings 558 at a lower end thereof. Through the fluid openings 558, the first fluid conduit 150 is in fluid communication with the reservoir 430.

Referring again to FIG. 4, in the depicted embodiment, the second fluid conduit 152 does not extend into the reservoir 430. Rather, an open end of the second fluid conduit 152 is mated with opening 356 through the top piece 420 of the main body 112 such that the second fluid conduit 152 is in fluid communication with the reservoir 430.

As shown in FIGS. 1-4, first and second isolation valves 160 and 162 are coupled to the respective first and second fluid conduits 150 and 152 at portions thereof external to the reservoir 430. In one embodiment, the isolation valves 160 and 162 are manual (i.e., a user may manually actuate the valves 160 and 162 to prevent fluid from flowing to and from the reservoir 430 through the fluid conduits 150 and 152).

Additionally, first and second connections (or fittings) 164 and 166 are coupled to the upper ends of the respective first and second fluid conduits 150 and 152. Although not shown in detail, the first and second connections 164 and 166 may be configured to detachably mate with other fluid lines for delivering fluids to and from the reservoir 430 through the first and second fluids conduits 150 and 152. Also, in the depicted embodiment, the fluid conduit assembly 114 includes a fill port 168 that extends through the top piece 420 of the main body 112 and is in fluid communication with the reservoir 430.

During operation, a processing liquid (or liquid source) is delivered into the reservoir 430 of the inner shell 416 of the main body 112, such as through the fill port 168. Examples of processing liquids include, but are not limited to, trimethylaluminium (TMA), tetraethyl orthosilicate (TEOS), metal-organic precursors for hafnium, and metal-organic precursors for molybdenum. In order to control the temperature of the liquid (and thus control the evaporation of the liquid), the thermoelectric modules 422 are provided with power. In some embodiments in which the first sides 542 of the thermoelectric modules 422 are adjacent to the sidewall 424 of the inner shell 416, heat is transferred from the reservoir 430 (and/or the processing liquid) to the outer shell 418. The heat may then be conducted to the cooling fins 440.

In order to enhance evaporation of the processing liquid, a carrier gas is delivered into the reservoir 430 through the first fluid conduit 150. Examples of carrier gasses include, but are not limited to, argon, krypton, helium, and nitrogen.

In embodiments in which the first fluid conduit 150 extends into the processing liquid, the carrier gas flows from the first fluid conduit 150 through the fluid openings 558, from which it transits, or “bubbles,” upwards through the processing liquid, as is commonly understood. However, in embodiments in which the first fluid conduit 150 does not extend into the processing liquid, the carrier gas transits, or flows, over the top of the processing liquid and may be used to limit the evaporation of the processing liquid.

Vapor from the processing liquid, along with the carrier gas, flows from the reservoir 430 through the second fluid conduit 152, and may then be delivered to a processing chamber of a substrate processing tool, such as that described below.

As heat is transferred to the outer shell 432, the temperature of the inner shell 416 (e.g., the sidewall 424 of the inner shell 416 and the processing liquid) is reduced such that any moisture enclosed within the bounded gap 436 may condense within the gap 436 on the sidewall 424 of the inner shell 416. Because the gap 436 is enclosed (and/or evacuated and/or hermetically sealed), any moisture that drips from the sidewall 424 is contained within the bubbler assembly 110, particularly within the gap 436. Thus, the bubbler assembly 110 described herein eliminates any issues resulting from moisture that may condense on the cold surfaces thereof.

Additionally, because of the gap 436, particularly in embodiments in which it is evacuated, unwanted heat transfer between the inner shell 416 and the outer shell 418 is minimized, thus improving the efficiency of the bubbler assembly 110. Efficiency is further improved due to the minimal thermal interfaces between the inner shell 416 and the outer shell 418 (i.e., the thermoelectric modules 422 provide the only direct contact points between the sidewall 424 of the inner shell 416 and the sidewall 432 of the outer shell 418). Further, because of the improved insulation provided by the gap 436, the thermoelectric modules 422 may provide sufficient heat transfer, eliminating the need for a liquid coolant.

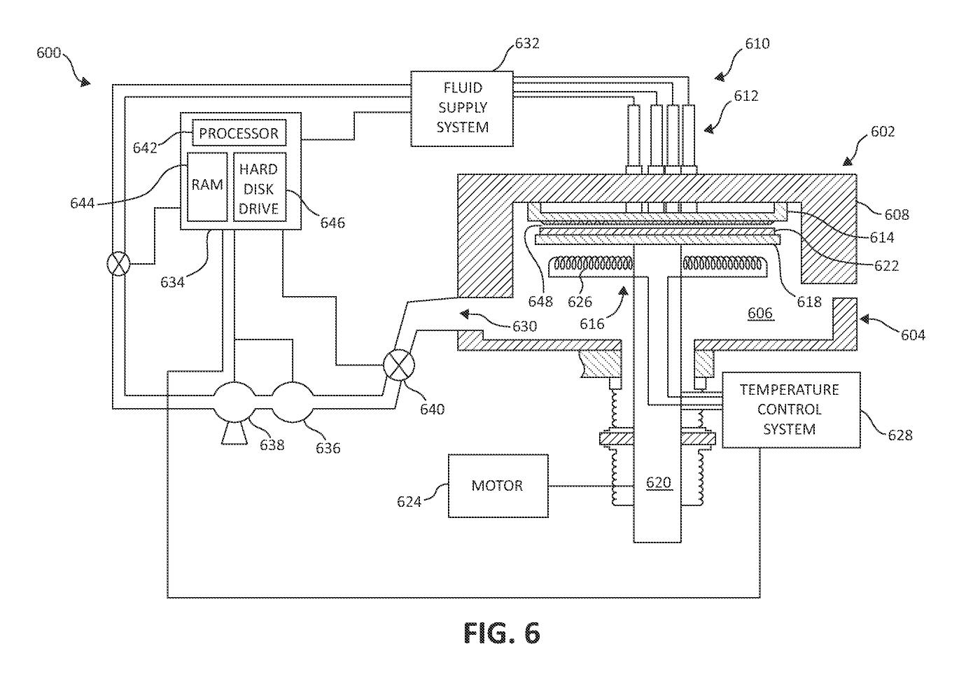

FIG. 6 illustrates a substrate processing system 600 in accordance with some embodiments of the present invention. The substrate processing system 600 includes an enclosure assembly 602 formed from a process-compatible material, such as aluminum or anodized aluminum. The enclosure assembly 602 includes a housing 604, which defines a processing chamber 606, and a vacuum lid assembly 608 covering an opening to the processing chamber 606 at an upper end thereof. Although only shown in cross-section, it should be understood that the processing chamber 606 is enclosed on all sides by the housing 604 and/or the vacuum lid assembly 608.

A process fluid injection assembly 610 is mounted to the vacuum lid assembly 608 and includes a plurality of injection ports 612 and a showerhead 614 to deliver reactive and carrier fluids into the processing chamber 606.

The processing system 600 also includes a heater/lift assembly 616 disposed within the processing chamber 606. The heater/lift assembly 616 includes a support pedestal (or substrate support) 618 connected to an upper portion of a support shaft 620. The support pedestal 618 may be formed from any process-compatible material, including aluminum nitride and aluminum oxide. The support pedestal 618 is configured to hold or support a substrate 622. The substrate 622 may be, for example, a semiconductor substrate (e.g., silicon) having a diameter of, for example, 200 or 300 mm.

The support pedestal 618 may be a vacuum chuck, as is commonly understood, or utilize other conventional techniques, such as an electrostatic chuck (ESC) or physical clamping mechanisms, to prevent the substrate 622 from moving on the support pedestal 618. The support shaft 620 is moveably coupled to the housing 604 so as to vary the distance between support pedestal 618 and the showerhead 614 using a motor 624.

Additionally, the heater/lift assembly 616 includes an inductive heating sub-system that includes one or more conductive coils (or members) 626 mounted below the substrate support 618 that are coupled to a power supply within a temperature control system 128.

The housing 604, the support pedestal 618, and the showerhead 614 are sized and shaped to create a peripheral flow channel that surrounds the showerhead 614 and the support pedestal 618 and provides a path for fluid flow to a pump channel 630 in the housing 604.

Still referring to FIG. 6, the processing system 600 also includes a fluid supply system 632 and a controller (or control system) 634. The fluid supply system 632 is in fluid communication with the injection ports 612 through a sequence of conduits (or fluid lines) and includes supplies of various processing fluids (e.g., gases). The bubbler assembly 110 described above and shown in FIGS. 1-5 may be implemented within the fluid supply system 632. As such, the bubbler assembly 110 may be in fluid communication with a gas supply (or processing fluid supply) within the fluid supply system 632 through the first fluid conduit 150 and with the processing chamber 606 through the second fluid conduit 152.

The fluid supply system 632 (and/or the controller 634) controls the flow of processing fluids to, from, and within the processing chamber 606 with a pressure control system that includes, in the embodiment shown, a turbo pump 636 and a roughing pump 638. The turbo pump 636 and the roughing pump 638 are in fluid communication with the processing chamber 606 via a butterfly valve 640 through the pump channel 630.

The controller 634 includes a processor 642 and memory, such as random access memory (RAM) 644 and a hard disk drive 646. The controller 634 is in operable communication with the various other components of the processing system 610, including the turbo pump 636, the temperature control system 628, the fluid supply system 632, and the motor 624 and controls the operation of the entire processing system to perform the methods and processes described herein.

During operation, the processing system 600 establishes conditions in a processing region 648 between the upper surface of the substrate 622 on the support pedestal 618 and the showerhead 614 to form a layer of material on the surface of the substrate 622, such as a thin film. The processing technique used to form the material may be, for example, a chemical vapor deposition (CVD) process, such as atomic layer deposition (ALD) or metalorganic chemical vapor deposition (MOCVD). During the formation of the layer, power is provided to the conductive coils 626 by the temperature control system 628 such that current flows through the conductive coils, causing the substrate 622 to be inductively heated.

Thus, in one embodiment, a substrate processing bubbler assembly is provided. The substrate processing bubbler assembly includes an inner shell, an outer shell, and a thermoelectric device. The inner shell is configured to hold a liquid. The outer shell at least partially surrounds the inner shell. The inner shell and the outer shell are sized and shaped such that a gap is formed between the inner shell and the outer shell. The thermoelectric device interconnects the inner shell and the outer shell. The thermoelectric device has a first side adjacent to the inner shell and a second side adjacent to the outer shell and is configured to transfer heat between the first side and the second side thereof.

In another embodiment, a substrate processing bubbler assembly is provided. The substrate processing bubbler assembly includes an inner shell, an outer shell, and a plurality of thermoelectric devices. The inner shell is configured to hold a liquid. The outer shell surrounds the inner shell. The inner shell and the outer shell are sized and shaped such that a hermetically sealed gap is formed between the inner shell and the outer shell. The gap circumscribes the inner shell. The plurality of thermoelectric devices are positioned within the gap and interconnect the inner shell and the outer shell. Each of the thermoelectric devices includes a first side adjacent to the inner shell and a second side adjacent to the outer shell and is configured to transfer heat from the first side to the second side thereof. The plurality of thermoelectric devices are spaced around a periphery of the inner shell.

In a further embodiment, a substrate processing system is provided. The substrate processing system includes a housing, a substrate support, a bubbler assembly, and a processing fluid supply. The housing defines a processing chamber. The substrate support is coupled to the housing and configured to support a substrate within the processing chamber. The bubbler assembly is in fluid communication with the processing chamber. The bubbler assembly includes an inner shell, an outer shell, and a thermoelectric device. The inner shell is configured to hold a liquid. The outer shell surrounds the inner shell. The inner shell and the outer shell are sized and shaped such that a gap is formed between the inner shell and the outer shell. The gap circumscribes the inner shell. The thermoelectric device interconnects the inner shell and the outer shell. The thermoelectric device has a first side adjacent to the inner shell and a second side adjacent to the outer shell and is configured to transfer heat between the first side and the second side thereof. The processing fluid supply in fluid communication with the bubbler assembly.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A bubbler assembly comprising:
an inner shell configured to hold a liquid;
an outer shell at least partially surrounding the inner shell; and
a thermoelectric device interconnecting the inner shell and the outer shell, the thermoelectric device having a first side adjacent to the inner shell and a second side adjacent to the outer shell, the thermoelectric device being configured to transfer heat between the first side and the second side thereof.

2. The bubbler assembly of claim 1, wherein a gap formed between the inner shell and the outer shell at least partially surrounds the inner shell.

3. The bubbler assembly of claim 2, wherein the inner shell comprises at least one side wall and first and second ends interconnected by the at least one side wall.

4. The bubbler assembly of claim 3, wherein the gap is adjacent to the at least one side wall of the inner shell and the second end of the inner shell.

5. The bubbler assembly of claim 4, wherein the gap is hermetically sealed.

6. The bubbler assembly of claim 5, further comprising a plurality of cooling fins coupled to the outer shell.

7. The bubbler assembly of claim 3, wherein the first end of the inner shell comprises a first opening and a second opening extending through the first end of the inner shell.

8. The bubbler assembly of claim 7, further comprising a tube in fluid communication with the first opening through the first end of the inner shell, wherein the tube extends from the first end of the inner shell towards the second end of the inner shell such that when a carrier gas is delivered through the tube into the inner shell, the carrier gas transits through a processing liquid within the inner shell.

9. The bubbler assembly of claim 7, further comprising a tube in fluid communication with the first opening through the first end of the inner shell, wherein the tube extends from the first end of the inner shell towards the second end of the inner shell such that when a carrier gas is delivered through the tube into the inner shell, the carrier gas transits over a processing liquid within the inner shell.

10. The bubbler assembly of claim 3, wherein the first end of the inner shell extends beyond a periphery of the at least one side wall of the inner shell and is in contact with the outer shell, and further comprising an annular sealing member between the first end of the inner shell and the outer shell.

11. A bubbler assembly comprising:
an inner shell configured to hold a liquid;
an outer shell surrounding the inner shell, wherein the inner shell and the outer shell are sized and shaped such that a hermetically sealed gap is formed between the inner shell and the outer shell, wherein the gap circumscribes the inner shell; and
a plurality of thermoelectric devices positioned within the gap and interconnecting the inner shell and the outer shell, each of the thermoelectric devices comprising a first side adjacent to the inner shell and a second side adjacent to the outer shell and being configured to transfer heat from the first side to the second side thereof.

12. The bubbler assembly of claim 11, wherein the inner shell comprises at least one side wall and first and second ends interconnected by the at least one side wall, wherein the first end of the inner shell extends beyond a periphery of the at least one side wall of the inner shell and is in contact with the outer shell, and wherein the gap is adjacent to the at least one side wall of the inner shell and the second end of the inner shell.

13. The bubbler assembly of claim 12, further comprising an annular sealing member between the first end of the inner shell and the outer shell.

14. The bubbler assembly of claim 13, further comprising a plurality of cooling fins coupled to the outer shell.

15. The bubbler assembly of claim 14, wherein the first end of the inner shell comprises a first opening and a second opening extending through the first end of the inner shell, and further comprising a tube in fluid communication with the first opening through the first end of the inner shell, wherein the tube extends from the first end of the inner shell towards the second end of the inner shell such that when a carrier gas is delivered through the carrier tube into the inner shell, the carrier gas transits through a processing liquid within the inner shell.

16. The bubbler assembly of claim 14, wherein the first end of the inner shell comprises a first opening and a second opening extending through the first end of the inner shell, and further comprising a tube in fluid communication with the first opening through the first end of the inner shell, wherein the tube extends from the first end of the inner shell towards the second end of the inner shell such that when a carrier gas is delivered through the tube into the inner shell, the carrier gas transits over a processing liquid within the inner shell.

17. A substrate processing system comprising:
a housing defining a processing chamber;
a substrate support coupled to the housing and configured to support a substrate within the processing chamber;
a bubbler assembly in fluid communication with the processing chamber, the bubbler assembly comprising:
an inner shell configured to hold a liquid;
an outer shell surrounding the inner shell, wherein the inner shell and the outer shell are sized and shaped such that a gap is formed between the inner shell and the outer shell; and
a thermoelectric device interconnecting the inner shell and the outer shell, the thermoelectric device having a first side adjacent to the inner shell and a second side adjacent to the outer shell and being configured to transfer heat between the first side and the second side thereof; and
a processing fluid supply in fluid communication with the bubbler assembly.

18. The substrate processing system of claim 17, wherein the bubbler assembly further comprises plurality of cooling fins coupled to the outer shell.

19. The substrate processing system of claim 18, wherein the gap is hermetically sealed.

20. The substrate processing system of claim 19, wherein the inner shell of the bubbler assembly comprises at least one side wall and first and second ends interconnected by the at least one side wall, and wherein the first end of the inner shell of the bubbler assembly extends beyond a periphery of the at least one side wall of the inner shell and is in contact with the outer shell, and wherein the bubbler assembly further comprises annular sealing member between the first end of the inner shell and the outer shell.
